(19) United States
(12) Patent Application Publication
(10) Pub. No.: US 2018/0219554 A1
(43) Pub. Date: Aug. 2, 2018

(54) ATOMIC OSCILLATOR AND ELECTRONIC APPARATUS

(71) Applicant: Seiko Epson Corporation, Tokyo (JP)

(72) Inventors: Hidekazu KOBAYASHI, Hara (JP); Hidemitsu SORIMACHI, Matsumoto (JP)

(21) Appl. No.: 15/882,054

(22) Filed: Jan. 29, 2018

(30) Foreign Application Priority Data
Jan. 30, 2017 (JP) 2017-014833
Jan. 30, 2017 (JP) 2017-014834

(51) Int. Cl. H03L 7/26; H01S 1/06; G02B 27/09; H05H 3/04

(52) U.S. Cl. CPC H03L 7/26; H05H 3/04; G02B 27/0955; H01S 1/06

(57) ABSTRACT

An atomic oscillator includes: an atomic cell in which an alkali metal is sealed; a light-emitting element that emits light to be radiated to the alkali metal; a light-receiving element that receives the light transmitted through the atomic cell and outputs a signal in accordance with a light reception intensity of the light; and a lens that is disposed between the light-emitting element and the atomic cell, wherein a focal point of the lens is spaced apart from a portion of the light-emitting element from which the light is emitted.

### BACKGROUND

### 1. Technical Field

The present invention relates to an atomic oscillator and an electronic apparatus.

### 2. Related Art

Atomic oscillators that oscillate based on energy transition of alkali metal atoms such as rubidium or cesium are known to have high long-term frequency stability.

As such an atomic oscillator, JP-A-2011-237401 discloses an atomic timepiece including a vertical resonator surface-emitting laser, a quarter wavelength plate, a gaseous phase cell, and a detector. In this atomic timepiece, the quarter wavelength plate, the gaseous phase cell, and the detector are in a tilted posture relative to an emission surface of the vertical resonator surface-emitting layer. Thus, the amount of light from the vertical resonator surface-emitting layer that is reflected from the quarter wavelength plate, the gaseous cell, and the detector back to the vertical resonator surface-emitting layer is reduced.

However, in the atomic timepiece disclosed in JP-A-2011-237401, it is difficult to assemble the quarter wavelength plate, gaseous cell, and detector in a tilted manner. As a result, there is a problem that cost increases.

### SUMMARY

An advantage of some aspects of the invention is that it provides an atomic oscillator capable of improving oscillation characteristics while achieving low cost and provides an electronic apparatus and a vehicle including the atomic oscillator.

An atomic oscillator according to an application example includes: an atomic cell in which an alkali metal is sealed; a light-emitting element (light emitter; light source) that emits light to be radiated to the alkali metal; a light-receiving element (light receiver) that receives the light transmitted through the atomic cell and outputs a signal in accordance with a light reception intensity of the light; and a lens that is disposed between the light-emitting element and the atomic cell. The lens diverges or converges the light toward the atomic cell.

In the atomic oscillator, the lens disposed between the light-emitting element and the atomic cell causes the light from the light-emitting element to diverge or converge toward the atomic cell. Therefore, even when the light is reflected from the atomic cell, the light-receiving element, or the like, the reflected light can be concentrated at a position spaced apart from the light-emitting element (in particular, spaced apart, offset, or displaced from the portion from which the light is emitted). Therefore, the amount of reflected light that returns to be incident on the light-emitting element is reduced, and thus it is possible to reduce an output variation (a wavelength variation or an intensity variation) of the light-emitting element caused by the returned light. As a result, it is possible to improve the frequency characteristics of the atomic oscillator. Since it is not necessary to dispose the atomic cell, the light-receiving element, and the lens in a tilted posture as in JP-A-2011-237401, it is easy to assemble the atomic cell, the light-receiving element, and the lens. As a result, it is possible to achieve a low cost atomic oscillator.

An atomic oscillator according to an application example includes: an atomic cell in which an alkali metal is sealed; a light-emitting element that emits light to be radiated to the alkali metal; a light-receiving element that receives the light transmitted through the atomic cell and outputs a signal in accordance with a light reception intensity of the light; and a lens that is disposed between the light-emitting element and the atomic cell. The focal point of the lens is axially shifted along the optical axis of the lens from the portion of the light-emitting element from which the light is emitted.

In the atomic oscillator, the lens disposed between the light-emitting element and the atomic cell has a focal point at a position shifted from the portion of the light-emitting element from which the light is emitted in the optical axis direction. Therefore, even when the light is reflected from the atomic cell, the light-receiving element, or the like, the reflected light can be concentrated at a different position from the light-emitting element (in particular, the portion from which the light is emitted). Therefore, the amount of reflected light that returns to be incident on the light-emitting element is reduced, and thus it is possible to reduce an output variation (a wavelength variation or an intensity variation) of the light-emitting element caused by the returned light. As a result, it is possible to improve the frequency characteristics of the atomic oscillator. Since it is not necessary to dispose the atomic cell, the light-receiving element, and the lens in a tilted posture as in JP-A-2011-237401, it is easy to assemble the atomic cell, the light-receiving element, and the lens. As a result, it is possible to achieve a low cost atomic oscillator.

In the atomic oscillator according to the application example, it is preferable that the lens diverges the light toward the atomic cell.

Thus, it is possible to easily further reduce the amount of reflected light returned to the light-emitting element than when the lens emits converged light toward the atomic cell.

An atomic oscillator according to an application example includes: an atomic cell in which an alkali metal is sealed; a light-emitting element that emits light to be radiated to the alkali metal; a light-receiving element that receives the light transmitted through the atomic cell and outputs a signal in accordance with a light reception intensity of the light; and a lens that is disposed between the light-emitting element and the atomic cell. The lens emits the light toward the atomic cell in a direction that is tilted relative to an optical axis of the lens.

In the atomic oscillator, the lens disposed between the light-emitting element and the atomic cell emits the light from the light-emitting element toward the atomic cell in a direction that is tilted relative to the optical axis of the lens. Therefore, even when the light is reflected from the atomic cell, the light-receiving element, or the like, the reflected light can be concentrated at a posit ion offset/spaced apart from (a position shifted in a direction lateral to the optical axis of the lens) the light-emitting element (in particular, the portion from which the light is emitted). Therefore, the amount of reflected light that returns to be incident on the light-emitting element is reduced, and thus it is possible to reduce an output variation (a wavelength variation or an intensity variation) of the light-emitting element caused by the returned light. As a result, it is possible to improve the frequency characteristics of the atomic oscillator.

An atomic oscillator according to an application example includes: an atomic cell in which an alkali metal is sealed; a light-emitting element that emits light to be radiated to the alkali metal; a light-receiving element that receives the light transmitted through the atomic cell and outputs a signal in accordance with a light reception intensity of the light; and a lens that is disposed between the light-emitting element and the atomic cell. The portion of the light-emitting element from which the light is emitted is laterally spaced apart (offset or displaced) from the optical axis of the lens.

In the atomic oscillator, the portion of the light-emitting element from which the light is emitted is displaced from the optical axis of the lens. Therefore, even when the light is reflected from the atomic cell, the light-receiving element, or the like, the reflected light can be concentrated at a position offset/spaced apart from (a position shifted in a lateral direction relative to the optical axis of the lens) the light-emitting element (in particular, the portion from which the light is emitted). Therefore, the amount of reflected light that returns to be incident on the light-emitting element is reduced, and thus it is possible to reduce an output variation (a wavelength variation or an intensity variation) of the light-emitting element caused by the returned light. As a result, it is possible to improve the frequency characteristics of the atomic oscillator.

It is preferable that the atomic oscillator according to the application example further includes a light reduction filter that is disposed between the light-emitting element and the lens.

With this configuration, it is possible to easily control the intensity of the light to be radiated to the alkali metal. Since the returned light also passes through the light reduction filter, it is possible to further reduce the amount of light returned to the light-emitting element.

In the atomic oscillator according to the application example, it is preferable that the light reduction filter contains a substance that absorbs the light.

With this configuration, it is possible to reduce the amount of returned light that is formed when the light from the light-emitting element is reflected from the light reduction filter.

It is preferable that the atomic oscillator according to the application example further includes a reflection reduction layer that is disposed on the light reduction filter and reduces reflection of the light.

With this configuration, it is possible to reduce the amount of returned light that is formed when the light from the light-emitting element is reflected from the surface of the light reduction filter.

In the atomic oscillator according to the application example, it is preferable that a distance from the focal point of the lens to the portion of the light-emitting element from which the light is emitted is less than a focal length of the lens.

With this configuration, it is possible to effectively reduce the amount of light returned to the light-emitting element while causing the distance between the light-emitting element and the lens to be relatively small.

It is preferable that the atomic oscillator according to the application example further includes a package that accommodates the light-emitting element, and the package includes a window through which the light is transmitted.

With this configuration, it is possible to adjust the temperature of the light-emitting element independently from the atomic cell. As a result, it is possible to easily reduce output variation caused by a temperature variation of the light-emitting element.

It is preferable that the atomic oscillator according to the application example further includes a reflection reduction layer that is disposed on a surface of the window facing the light-emitting element and reduces reflection of the light.

With this configuration, it is possible to reduce the amount of returned light that is formed when the light from the light-emitting element is reflected from the window. Here, since the window of the package accommodating the light-emitting element is located at a position very close to the light-emitting element, the light from the light-emitting element is easily returned to be incident on the light-emitting element after the light is reflected from the window. Therefore, by reducing the amount of reflected light from the window, it is particularly effective to reduce the amount of light that is returned to the light-emitting element.

In the atomic oscillator according to the application example, it is preferable that the window is a light reduction filter.

With this configuration, it is possible to reduce the amount of returned light that is formed when the light from the light-emitting element is reflected from the light reduction filter. Since a light reduction filter formed outside of the package can be omitted, it is possible to simplify the configuration of the atomic oscillator.

An electronic apparatus according to an application example includes the atomic oscillator according to the foregoing application example.

In the electronic apparatus, it is possible to obtain the advantage (for example, excellent frequency characteristics) of the atomic oscillator and exert excellent characteristics.

A vehicle according to an application example includes the atomic oscillator according to the foregoing application example.

In the vehicle, it is possible to obtain the advantage (for example, excellent frequency characteristics) of the atomic oscillator and exert excellent characteristics.

### BRIEF DESCRIPTION OF THE DRAWINGS

Embodiments of the invention will be described with reference to the accompanying drawings, wherein like numbers reference like elements.

FIG. 1 is a schematic diagram illustrating an atomic oscillator according to an embodiment.

FIG. 2 is a sectional view illustrating the atomic oscillator illustrated in FIG. 1.

FIG. 3 is a sectional view illustrating a light-emitting element module included in the atomic oscillator illustrated in FIG. 2.

FIG. 4 is a schematic diagram illustrating a light path when a light-emitting element is disposed at the focal point of a condensing lens.

FIG. 5 is a schematic diagram illustrating a light path of the atomic oscillator illustrated in FIG. 2.

FIG. 6 is a graph illustrating a relation between a distance (position) from an optical axis illustrated in FIGS. 4 and 5 and the intensity of returned light.

FIG. 7 is a graph illustrating a relation between the intensity of the returned light and various conditions (A to M) when transmittance of a light reduction filter is 2%.

FIG. 8 is a graph illustrating a relation between the intensity of the returned light and the various conditions (A to M) when transmittance of alight reduction filter is 10%.

FIG. 9 is a graph illustrating a relation between the intensity of the returned light and the various conditions (A to M) when a refractive index of the condensing lens is 1.51.

FIG. 10 is a schematic diagram illustrating a light path of the atomic oscillator illustrated in FIG. 2.

FIG. 11 is a graph illustrating a relation between the intensity of the returned light and a distance (position) from the optical axis illustrated in FIGS. 4 and 10.

FIG. 12 is a graph illustrating a relation between the intensity of the returned light and various conditions (samples S1 to S8).

FIG. 13 is a schematic diagram illustrating a modification example of the atomic oscillator illustrated in FIG. 5.

FIG. 14 is a schematic diagram illustrating a modification example of the atomic oscillator illustrated in FIG. 10.

FIG. 15 is a diagram illustrating an overall configuration when the atomic oscillator according to the embodiment is used in a positioning system in which a GPS satellite is used.

FIG. 16 is a diagram illustrating an embodiment of a vehicle.

### DESCRIPTION OF EXEMPLARY EMBODIMENTS

Hereinafter, an atomic oscillator, an electronic apparatus, and a vehicle according to embodiments of the invention will be described with reference to the appended drawings.

### 1. Atomic Oscillator

First, an embodiment of an atomic oscillator will be described.

### First Embodiment

An atomic oscillator 1 according to a first embodiment will be described.

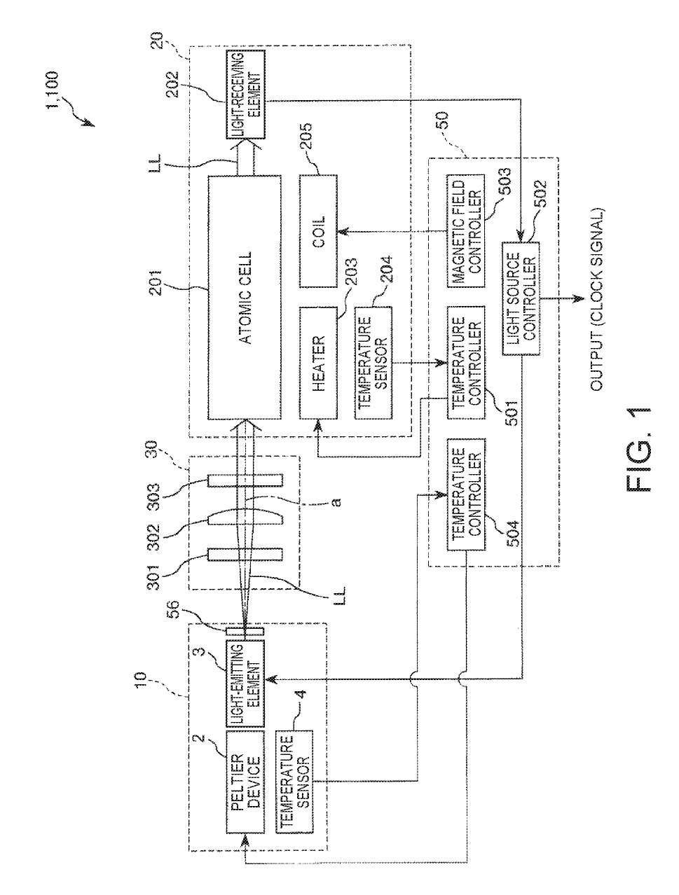

FIG. 1 is a schematic diagram illustrating the atomic oscillator according to the embodiment.

An atomic oscillator 1 illustrated in FIG. 1 is an atomic oscillator that uses coherent population trapping (CPT) in which a phenomenon occurs in which two pieces of resonance light are transmitted without being absorbed by alkali metal atoms when the two pieces of resonance light with specific different wavelengths are simultaneously radiated to the alkali metal atoms. The phenomenon of the coherent population trapping is also called an electromagnetically induced transparency (EIT) phenomenon.

As illustrated in FIG. 1, the atomic oscillator 1 includes a light-emitting element module 10, an atomic cell assembly 20, an optical system 30 installed be between the light-emitting element module 10 and the atomic cell assembly 20, and a controller 50 that controls operations of the light-emitting element module 10 and the atomic cell assembly 20. Hereinafter, an overview of the atomic oscillator 1 will be described first.

The light-emitting element module 10 includes a Peltier device 2, a light-emitting element 3, and a temperature sensor 4. The light-emitting element 3 emits linearly polarized light LL containing two types of light with different frequencies. The temperature sensor 4 measures temperature of the light-emitting element 3. The Peltier device 2 adjusts the temperature of the light-emitting element 3 (heats or cools the light-emitting element 3).

The optical system 30 includes a light reduction filter 301, a condensing lens (lens) 302, and a quarter wavelength plate 303. The light reduction filter 301 reduces the intensity of the light LL from the above-described light-emitting element 3. The condensing lens 302 adjusts the angle of radiation of the light LL (for example, renders the light LL into parallel light). The quarter wavelength plate 303 converts the two types of light with different frequencies contained in the light LL from linearly polarized light to circularly polarized light (right-handed circularly polarized light or left-handed circularly polarized light).

The atomic cell assembly 20 includes an atomic cell 201, a light-receiving element 202, a heater 203, a temperature sensor 204, and a coil 205.

The atomic cell 201 has light transmittance and alkali metal is sealed inside the atomic cell 201. An alkali metal atom has energy levels of three level systems formed by two different ground levels and an excited level. The light LL from the light-emitting element 3 is incident on the atomic cell 201 via the light reduction filter 301, the condensing lens 302, and the quarter wavelength plate 303. The light-receiving element 202 receives the light LL passing through the atomic cell 201 and outputs a signal in accordance with the light reception intensity.

The heater 203 heats the alkali metal inside the atomic cell 201 to change at least a part of the alkali metal into a gas state of a desired density. The temperature sensor 204 measures temperature of the atomic cell 201. The coil 205 applies a magnetic field in a predetermined direction to the alkali metal inside the atomic cell 201 to perform Zeeman splitting on the energy levels of the alkali metal atoms. When the circularly polarized resonance light pair described above is radiated to the alkali metal atoms in a state in which the alkali metal atoms are subjected to the Zeeman splitting in this way, the number of alkali metal atoms at a desired energy level among the plurality of levels at which the alkali metal atoms are subjected to the Zeeman splitting can be relatively greater than the number of alkali metal atoms at another energy level. Therefore, it is possible to increase the number of atoms realizing a desired EIT phenomenon, raise a desired EIT signal (a signal shown in the output signal of the light-receiving element 202 with the EIT phenomenon), and consequently improve the oscillation characteristics (in particular, short-term frequency stability) of the atomic oscillator 1.

The controller 50 includes a temperature controller 501, a light source controller 502, a magnetic field controller 503, and a temperature controller 504. Based on a measurement result of the temperature sensor 204, the temperature controller 501 controls conduction to the heater 203 such that a desired temperature is maintained inside the atomic cell 201. The magnetic field controller 503 controls conduction to the coil 205 such that the magnetic field generated by the coil 205 is constant. Based on a measurement result of the temperature sensor 4, the temperature controller 504 controls conduction to the Peltier device 2 such that the temperature of the light-emitting element 3 is maintained at a desired temperature (within a temperature region).

Based on a detection result of the light-receiving element 202, the light source controller 502 controls the frequencies of two types of light contained in the light LL from the light-emitting element 3 such that an EIT phenomenon occurs. Here, the EIT phenomenon occurs when the two types of light become the resonance light pair with a frequency difference equivalent to an energy difference between two ground levels of the alkali metal atoms inside the atomic cell 201. The light source controller 502 includes a voltage controlled quartz crystal oscillator (not illustrated) of which an oscillation frequency is controlled for stabilization in synchronization with control of the frequencies of the two types of light described above and outputs an output signal of the voltage controlled quartz crystal oscillator (VCXO) as an output signal (clock signal) of the atomic oscillator 1.

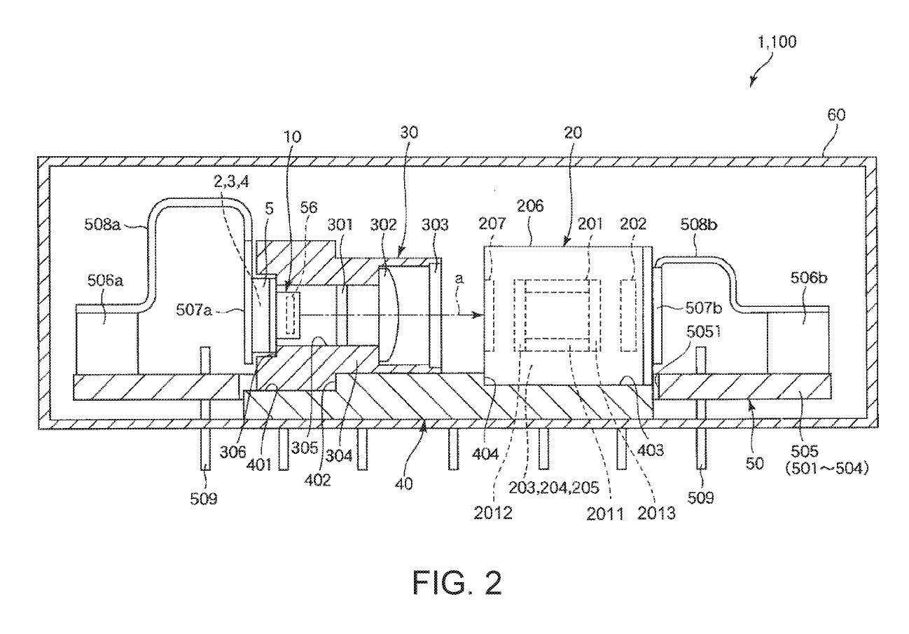

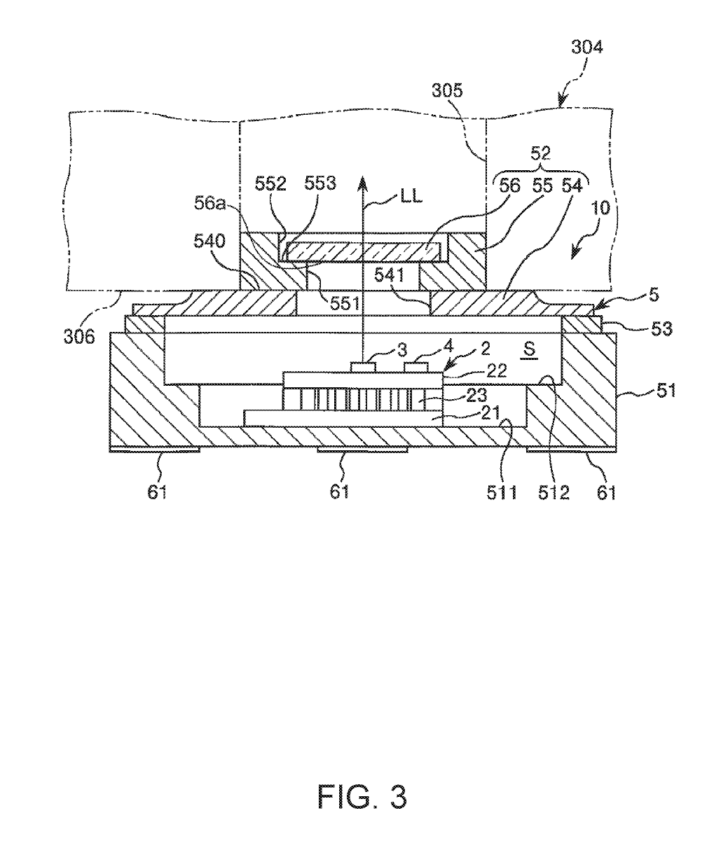

An overview of the atomic oscillator 1 has thus been described. Hereinafter, a more specific configuration of the atomic oscillator 1 will be described with reference to FIGS. 2 and 3.

FIG. 2 is a sectional view illustrating the atomic oscillator illustrated in FIG. 1. FIG. 3 is a sectional view illustrating a light-emitting element module included in the atomic oscillator illustrated in FIG. 2. Hereinafter, to facilitate the description, the upper side in FIG. 2 is referred to as a “top” and the lower side is referred to as a “bottom”.

As illustrated in FIG. 2, the atomic oscillator 1 includes a light-emitting element module 10, an atomic cell assembly 20, an optical system 30 that holds the light-emitting element module 10, a holder 40 that collectively holds the atomic cell assembly 20 and the optical system. 30, a controller 50 that is electrically connected to the light-emitting element module 10 and the atomic cell assembly 20, and a package 60 that accommodates them.

### Light-Emitting Element Module

As illustrated in FIG. 3, the light-emitting element module 10 includes the Peltier device 2, the light-emitting element 3, the temperature sensor 4, and a package 5 accommodating them.

The package 5 includes a base 51 that includes a recess 511 and a lid 52 that blocks an opening of the recess 511. An inner space S which is an airtight space in which the Peltier device 2, the light-emitting element 3, and the temperature sensor 4 are accommodated is formed between the base 51 and the lid 52. The inner space S of the package 5 is preferably in a depressurized (vacuum) state. Thus, it is possible to reduce an influence of a change in the external temperature of the package 5 on the light-emitting element 3, the temperature sensor 4, or the like accommodated in the inner space S and reduce a variation in the temperature of the light-emitting element 3, the temperature sensor 4, or the like. The inner space S of the package 5 may not be in the depressurized state and an inert gas such as nitrogen, helium, or argon may be sealed.

A material of the base 51 is not particularly limited. A material that has an insulation property and is suitable for forming the inner space S as an airtight space, for example, any of various kinds of ceramics such as oxide-based ceramics such as alumina, silica, titania, and zirconia, nitride-based ceramics such as silicon nitride, aluminum nitride, and titanium nitride, and carbide-based ceramics such as silicon carbide, can be used.

The base 51 includes a step 512 that is closer to the opening than the bottom surface of the recess 511 and surrounds the outer circumference of the bottom surface of the recess 511. A plurality of connection electrodes (internal electrodes) (not illustrated) are installed on the step 512. The connection electrodes are electrically connected to a plurality of external mounting electrodes 61 installed on the outer surface (the lower surface in the drawing) of the base 51 via through-electrodes (not illustrated) penetrating the base 51.

Materials of the external mounting electrodes 61 and the like are not particularly limited. For example, metal materials such as gold (Au), a gold alloy, platinum (Pt), aluminum (Al), an aluminum alloy, silver (Ag), a silver alloy, chromium (Cr), a chromium alloy, nickel (Ni), copper (Cu), molybdenum (Mo), niobium (Nb), tungsten (W), iron (Fe), titanium (Ti), cobalt (Co), zinc (Zn), and zirconium (Zr) can be exemplified.

A seal ring 53 with a frame shape (circular shape) is installed on the end surface of the base 51 on the side of the lid 52. The seal ring 53 is formed of, for example, a metal material such as Kovar and is joined to the base 51 by soldering or the like. The lid 52 is joined to the base 51 via the seal ring 53 by seam welding or the like.

The lid 52 includes a body 54 that has a plate shape, a protrusion 55 that is installed on the body 54 and has a cylindrical shape, and a window 56 that blocks (overlays) a hole 551 (opening) formed inside the protrusion 55.

A material of the body 54 is not particularly limited. A metal material is suitably used. It is preferable to use a metal material with a linear expansion coefficient similar to that of the material of the base 51. Accordingly, for example, when the base 51 is formed of a ceramics substrate, it is preferable to use an alloy such as Kovar as the material of the body 54.

The protrusion 55 includes a hole 551 that communicates with the hole 541 of the above-described body 54 and a hole 552 that communicates with the hole 551 opposite to the hole 541 with respect to the hole 551 therein. At least apart of the light LL from the light-emitting element 3 passes through each of the holes 551 and 552. Here, the width (diameter) of the hole 552 is greater than the width (diameter) of the hole 551. In this way, a step 553 is formed between the holes 551 and 552. The step 553 is parallel to a plate surface 540 of the above-described body 54. The step 553 may be tilted relative to the plate surface 540 of the body 54.

A material of the protrusion 55 may be different from the material of the body 54. However, it is preferable to use a metal material with a linear expansion coefficient similar to that of the material of the body 54 and it is more preferable to use the same material as the material of the body 54. The protrusion 55 may be formed to be separate from the body 54 to be joined (fixed) by a known joining method or may be formed to be integrated (collectively) with the body 54 using a mold.

In the package 5, the window 56 formed of a plate-shaped member through which the light LL is transmitted is installed inside the hole 552. The window 56 is joined onto the above-described step 553 by a known joining method and blocks the opening of the hole 551 of the above-described protrusion 55 on the side of the hole 552. Here, since the step 553 is parallel to the plate surface 540 of the body 54, as described above, the step 553 is accordingly parallel to the surface 56a of the window 56 on the side of the light-emitting element 3 or the plate surface 540 of the body 54. The window 56 may be tilted relative to the plate surface 540 of the body 54 as in the above-described step 553.

A material of the window 56 is not particularly limited. For example, a glass material can be exemplified. The window 56 may be an optical component such as a lens or a light reduction filter or may have, for example, a functional film such as a reflection reduction layer 57 to be described below on the surface 56a of the window 56.

On the lid 52, the body 54 and the protrusion 55 engage with the holder 304 of the optical system 30, which will be described below, to be positioned. More specifically, the plate surface 540 of the body 54 comes into contact with a positioning surface 306 of the holder 304, so that the lid 52 is positioned in the emission direction of the light LL. When the protrusion 55 is inserted into the through-hole 305 of the holder 304 and side surfaces of the protrusion 55 come into contact with the inner wall surface of the through-hole 305, the lid 52 is positioned in the emission direction of the light LL. By bringing the body 54 and the protrusion 55 into contact with the holder 304 in this way, it is possible to lower the temperature of the lid 52 through heat dissipation from the holder 304 formed of a metal material and thus having a heat dissipation property.

The Peltier device 2 is disposed on the bottom surface of the recess 511 of the base 51 of the package 5. The Peltier device 2 is fixed to the base 51 by, for example, an adhesive. The Peltier device 2 includes a pair of substrates 21 and 22 and a joint 23 installed between the substrates 21 and 22. The substrates 21 and 22 are formed of a material that has excellent thermal conductivity, such as a metal material or a ceramics material. Insulation films are formed on the surfaces of the substrates 21 and 22, as necessary.

The Peltier device 2 is electrically connected to a connection electrode (not illustrated) installed in the package 5 via an interconnection (not illustrated) (an interconnection including a bonding wire). In the Peltier device 2, one of the substrates 21 and 22 serves as a heat generator side and the other substrate serves as a heat absorber side by the Peltier effect generated in the joint 23. Here, in the Peltier device 2, a state in which the substrate 21 serves as the heat generator side and the substrate 22 serves as the heat absorber side and a state in which the substrate 21 serves as the heat absorber side and the substrate 22 serves as the heat generator side can be switched according to a direction of a current to be supplied. Therefore, even when the range of an ambient temperature is broad, the temperature of the light-emitting element 3 or the like can be adjusted to (or maintained at) a desired temperature (target temperature). Thus, it is possible to further reduce an adverse influence (for example, a variation in the wavelength of the light LL) due to a change in temperature. Here, a target temperature of the light-emitting element 3 can be selected depending on the characteristics of the light-emitting element 3 and is not particularly limited. For example, the target temperature is equal to or greater than about 30° C. and equal to or less than about 40° C.

The light-emitting element 3 is, for example, a semiconductor laser such as a vertical resonator surface-emitting laser (VCSEL). The semiconductor laser can emit two types of light with different wavelengths by superimposing a high-frequency signal on a direct-current bias current (performing modulation) for use. In the embodiment, the light emitted from the light-emitting element 3 is linearly polarized. The light-emitting element 3 is electrically connected to a connection electrode (not illustrated) installed in the package 5 via an interconnection (not illustrated) (an interconnection including a bonding wire).

The temperature sensor 4 is, for example, a temperature measurement element such as a thermistor or a thermocouple. The temperature sensor 4 is electrically connected to a connection electrode (not illustrated) installed in the package 5 via an interconnection (not illustrated) (an interconnection including a bonding wire).

### Optical System

As illustrated in FIG. 2, the optical system 30 includes the light reduction filter 301, the condensing lens 302, the quarter wavelength plate 303, and a holder 304 that holds them. Here, the holder 304 includes through-holes 305 of which both ends are open. The through-hole 305 is a passage region of the light LL. The light reduction filter 301, the condensing lens 302, and the quarter wavelength plate 303 are disposed in this order inside the through-hole 305. The light reduction filter 301, the condensing lens 302, and the quarter wavelength plate 303 are fixed to the holder 304 by an adhesive or the like (not illustrated). The holder 304 is formed of, for example, a metal material such as aluminum and has a heat dissipation property.

As described above, the light reduction filter 301 has a function of reducing the intensity of the light LL from the light-emitting element 3. The light reduction filter 301 is not particularly limited and may be an absorption type or reflection type filter. The condensing lens 302 has a function of adjusting an angle of radiation of the light LL (for example, rendering the light LL into parallel light). Thus, it is possible to reduce a change in the power density of the light LL in its traveling direction inside the atomic cell 201 and prevent a line width of an EIT signal from spreading. As a result, it is possible to improve the oscillation characteristics (in particular, short-term frequency stability) of the atomic oscillator 1. The quarter wavelength plate 303 has a function of converting two types of light with different frequencies contained in the light LL from linearly polarized light to circularly polarized light (right-handed circularly polarized light or left-handed circularly polarized light). Thus, it is possible to increase the intensity of the EIT signal by interaction with a magnetic field from the coil 205.

In the optical system 30, the light reduction filter 301 may be omitted depending on the intensity of the light LL from the light-emitting element 3. The optical system 30 may include an optical element in addition to the light reduction filter 301, the condensing lens 302, and the quarter wavelength plate 303. A disposition order of the light reduction filter 301, the condensing lens 302, and the quarter wavelength plate 303 is not limited to the illustrated order, and the light reduction filter 301, the lens 302, and the quarter wavelength plate 303 may be disposed in any order. The light reduction filter 301, the condensing lens 302, and the quarter wavelength plate 303 have any attitude.

### Atomic Cell Assembly

The atomic cell assembly 20 includes the atomic cell 201, a light-receiving element 202, a heater 203, a temperature sensor 204, a coil 205, and a package 206 that accommodates them.

An alkali metal such as rubidium, cesium, or sodium in a gaseous form is sealed inside the atomic cell 201. In the atomic cell 201, a noble gas such as argon or neon or an inert gas such as nitrogen may be sealed as a buffer gas along with the alkali metal gas as necessary.

Although not illustrated in great detail, the atomic cell 201 includes, for example, a trunk portion 2011 that has a through-hole with a pillar shape and one pair of windows 2012 and 2013 that form an inner space sealed airtight by sealing both openings of the through-hole of the trunk portion 2011. Here, the light LL incident on the atomic cell 201 is transmitted through the one window 2012 and the light LL emitted from the inside of the atomic cell 201 is transmitted through the other window 2013. Accordingly, a material used to form the windows 2012 and 2013 may have transmittance with respect to the light LL and is not particularly limited. For example, a glass material or a quartz crystal can be exemplified. On the other hand, a material used to form the trunk portion 2011 is not particularly limited and a metal material, a glass material, a silicon material, and a quartz crystal can be exemplified. From the viewpoint of workability or joining with the windows 2012 and 2013, it is preferable to use a glass material or a silicon material. A method of joining the trunk portion 2011 with the windows 2012 and 2013 can be determined according to the material and is not particularly limited. For example, a direct joining method, an anode joining method, a melting joining method, or an optical joining method can be used.

The light-receiving element 202 is disposed to be opposite to the light-emitting element module 10 with respect to the atomic cell 201. The light-receiving element 202 is not particularly limited as long as the light-receiving element can detect the intensity of the light LL (the resonance light pair) transmitted through the atomic cell 201. For example, a light detector (light-receiving element) such as a photodiode is exemplified.

Although not illustrated in great detail, for example, the heater 203 is disposed on the above-described atomic cell 201 or is connected to the atomic cell 201 via a thermal conductive member such as a metal. The heater 203 is not particularly limited as long as the atomic cell 201 (more specifically, the alkali metal inside the atomic cell 201) can be heated. For example, a Peltier device or any of various heaters having a heating resistor can be exemplified.

Although not illustrated in great detail, for example, the temperature sensor 204 is disposed near the atomic cell 201 or the heater 203. The temperature sensor 204 is not particularly limited as long as the temperature of the atomic cell 201 or the heater 203 can be detected. For example, various known temperature sensors such as a thermistor or a thermocouple can be exemplified.

Although not illustrated in great detail, for example, the coil 205 is a solenoid type coil disposed to be wound around the outer circumference of the atomic cell 201 or a pair of Helmholtz coils facing each other with the atomic cell 201 interposed therebetween. The coil 205 generates a magnetic field in a direction (a parallel direction) along the optical axis of the light LL inside the atomic cell 201. In this way, a gap between different energy levels at which the alkali metal atoms inside the atomic cell 201 are degenerated can be spread by Zeeman splitting to improve a resolution and the line width of the EIT signal can be reduced. The magnetic field generated by the coil 205 may be one magnetic field between a direct-current magnetic field and an alternating-current magnetic field or may be a magnetic field in which a direct-current magnetic field and an alternating-current magnetic field are superimposed.

Although not illustrated in great detail, the package 206 includes, for example, a plate-shaped substrate and a cover joined to the substrate. An airtight space in which the atomic cell 201, the light-receiving element 202, the heater 203, the temperature sensor 204, and the coil 205 described above are accommodated is formed between the substrate and the cover. Here, the substrate directly or indirectly holds the atomic cell 201, the light-receiving element 202, the heater 203, the temperature sensor 204, and the coil 205. A plurality of terminals electrically connected to the light-receiving element 202, the heater 203, the temperature sensor 204, and the coil 205 are installed on the outer surface of the substrate. On the other hand, the cover forms a bottom cylinder of which one end is open and the opening is blocked by the substrate. A window 207 that has transmittance for the light LL is installed at the other end (bottom portion) of the cover.

A material of the portions other than the window 207 of the cover and the substrate of the package 206 is not particularly limited. For example, a ceramics or a metal can be exemplified. As a material of the window 207, for example, a glass material can be exemplified. A method of joining the substrate to the cover is not particularly limited. For example, soldering, seam welding, or energy line welding (laser welding, electron beam welding, or the like) can be exemplified. It is preferable that the package 206 is internally depressurized than the atmospheric pressure. Thus, it is possible to control the temperature of the atomic cell 201 simply and with high precision. As a result, it is possible to improve the characteristics of the atomic oscillator 1. When the airtight space is not formed inside the package 206, the window 207 may be omitted.

### Holder

The holder 40 is formed in a plate shape. The atomic cell assembly 20 and the optical system 30 described above are placed on one surface of the holder 40. The holder 40 has an installation surface 401 formed along the shape of the lower surface of the holder 304 of the optical system 30. A step 402 is formed on the installation surface 401. The step 402 engages with the step of the lower surface of the holder 304 and regulates movement of the holder 304 toward the side of the atomic cell assembly 20 (the right side of FIG. 2). Similarly, the holder 40 has an installation surface 403 formed along the shape of the lower surface of the package 206 of the atomic cell assembly 20. A step 404 is formed on the installation surface 403. The step 404 engages with the end surface of the package 206 (the end surface on the left side of FIG. 2) and regulates movement of the package 206 toward the side of the optical system 30 (the left side of FIG. 2).

In this way, the holder 40 can regulate a relative positional relation between the atomic cell assembly 20 and the optical system 30. Thus, since the light-emitting element module 10 is fixed to the holder 304, a relative positional relation of the light-emitting element module 10 relative to the atomic cell assembly 20 and the optical system 30 is also regulated. Here, the package 206 and the holder 304 are fixed to the holder 40 by a fixing member such as a screw (not illustrated). The holder 40 is fixed to the package 60 by a fixing member such as a screw (not illustrated). The holder 40 is formed of, for example, a metal material such as aluminum and has a heat dissipation property. Thus, it is possible to efficiently dissipate the heat from the light-emitting element module 10.

### Controller

As illustrated in FIG. 2, the controller 50 is installed to be adjacent to the light-emitting element module 10 and the atomic cell assembly 20. The controller 50 includes a circuit substrate 505, two connectors 506a and 506b installed on the circuit substrate 505, a rigid wiring substrate 507a connected to the light-emitting element module 10, a rigid wiring substrate 507b connected to the atomic cell assembly 20, a flexible wiring substrate 508a connecting the connector 506a to the rigid wiring substrate 507a, a flexible wiring substrate 508b connecting the connector 506b to the rigid wiring substrate 507b, and a plurality of lead pins 509 penetrating the circuit substrate 505.

Here, an integrated circuit (IC) chip (not illustrated) is installed in the circuit substrate 505. The IC chip functions as the temperature controller 501, the light source controller 502, the magnetic field controller 503, and the temperature controller 504 described above. The circuit substrate 505 includes a through-hole 5051 into which the above-described holder 40 is inserted. The circuit substrate 505 is held by the package 60 via the plurality of lead pins 509. The plurality of lead pins 509 penetrate inside and outside the package 60 and are electrically connected to the circuit substrate 505.

The configuration in which the circuit substrate 505 is electrically connected to the light-emitting element module 10 and the configuration in which the circuit substrate 505 is electrically connected to the atomic cell assembly 20 are not limited to the connectors 506a and 506b, the rigid wiring substrates 507a and 507b, and the flexible wiring substrates 508a and 508b illustrated in the drawing, but other known connectors and wirings may be used.

The package 60 is formed of, for example, a metal material such as Kovar, and thus has a magnetic shielding property. Thus, it is possible to reduce an adverse influence of an external magnetic field on the characteristics of the atomic oscillator 1. The inside of the package 60 may be depressurized or may be under the atmospheric pressure, but is preferably an airtight space.

In the above-described atomic oscillator 1, the light LL emitted from the light-emitting element 3 is transmitted through the window 56, the light reduction filter 301, the condensing lens 302, the quarter wavelength plate 303, and the atomic cell 201 in this order to be received by the light-receiving element 202. At this time, if a part of the light LL is reflected from at least one of the window 56, the light reduction filter 301, the condensing lens 302, the quarter wavelength plate 303, the atomic cell 201, and the light-receiving element 202 and is incident as returned light with high intensity on the light-emitting element 3, there is a concern that an output variation (a wavelength variation or an intensity variation) of the light-emitting element 3 could occur. Accordingly, the atomic oscillator 1 has a configuration in which the intensity of the returned light can be reduced. Hereinafter, the configuration of the atomic oscillator 1 will be described in detail.

### Light Path of Light-Emitting Element

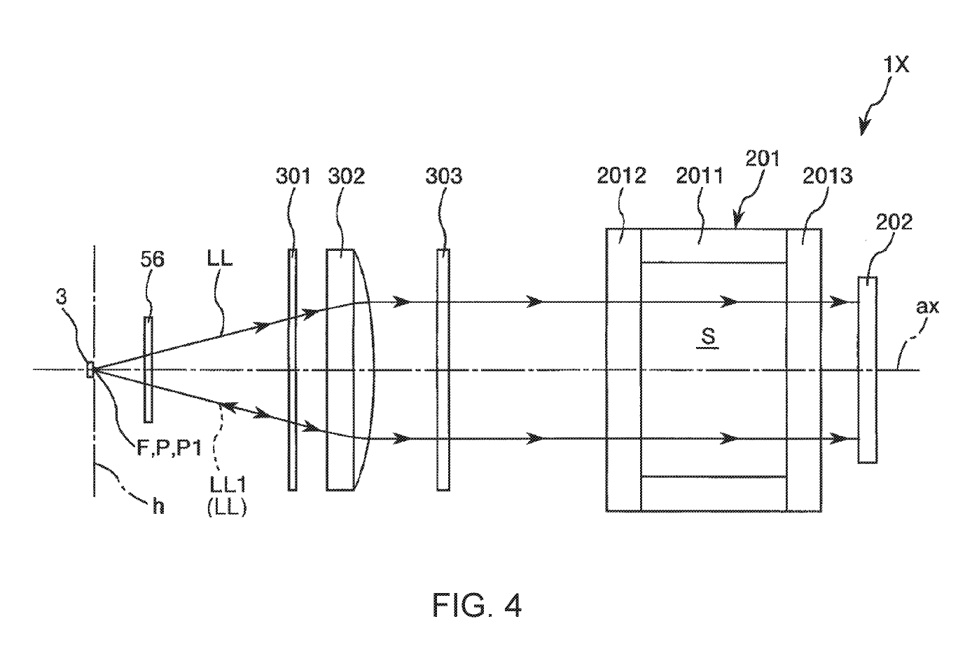

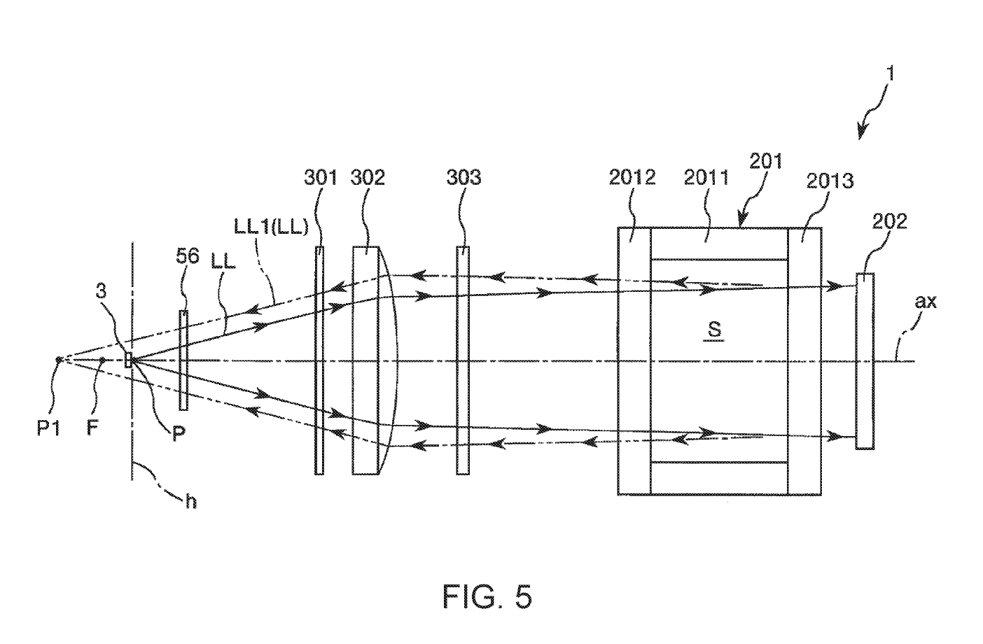

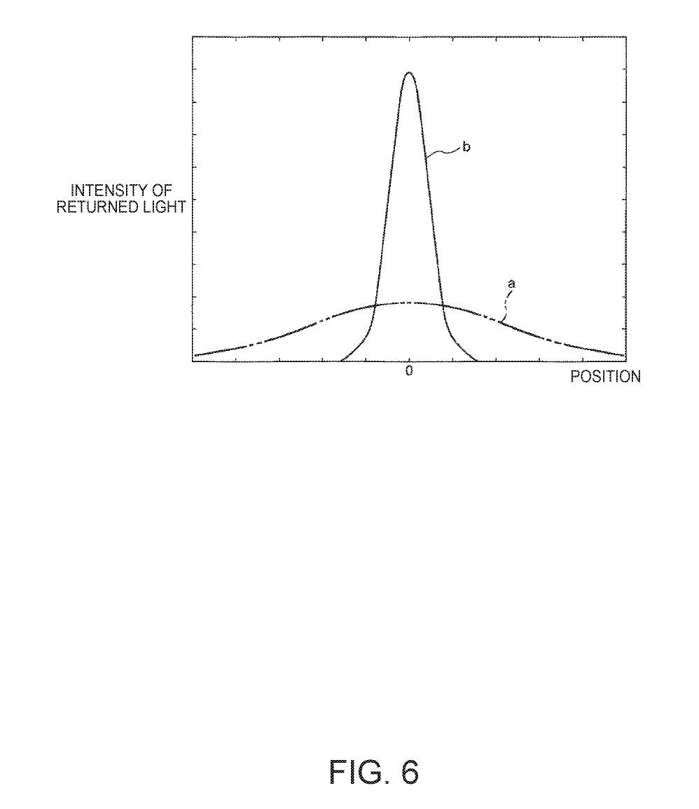

FIG. 4 is a schematic diagram illustrating a light path when a light-emitting element is disposed at the focal point of a condensing lens. FIG. 5 is a schematic diagram illustrating a light path of the atomic oscillator 1 illustrated in FIG. 2 (when the light-emitting element is disposed at a position shifted from a focal point of the condensing lens). FIG. 6 is a graph illustrating a relation between a distance (position) from an optical axis illustrated in FIGS. 4 and 5 and the intensity of returned light (returned light when only light concentrated by the condensing lens is considered).

As described above, the condensing lens 302 reduces a change in power density of the light LL in the travelling direction in the atomic cell 201 by rendering the light LL into parallel light and contributes to an improvement in oscillation characteristics (in particular, short-term frequency stability) of the atomic oscillator.

However, when the light LL emitted from the condensing lens 302 becomes parallel light as in an atomic oscillator 1X (a comparative example) illustrated in FIG. 4 (a light path indicated by a solid line), that is, when a position P of a light emission portion of the light-emitting element 3 (a portion from which the light LL is emitted) matches a focal point F which is a focal point of the condensing lens 302 on the side of the light-emitting element 3, returned light LL1 which is reflected light returns along the same light path (a light path indicated by a solid line) as the original light path to be concentrated at the focal point F after the light LL is reflected from the quarter wavelength plate 303, the windows 2012 and 2013 of the atomic cell 201, or the light-receiving element 202. That is, in this case, the condensing point P1 (beam waist) of the returned light LL1 matches the focal point F. Therefore, in the case illustrated in FIG. 4, there is a problem that the returned light LL1 is incident with high intensity on the light emission portion of the light-emitting element 3 and an output variation of the light-emitting element 3 occurs.

Accordingly, as illustrated in FIG. 5, the atomic oscillator 1 is configured such that the light LL emitted from the condensing lens 302 is not parallelized to be incident on the atomic cell 201. That is, the atomic oscillator 1 is configured such that the position P of the light emission portion of the light-emitting element 3 (the portion from which the light LL is emitted) does not match (is offset/spaced apart from) the focal point F which is a focal point of the condensing lens 302 on the side of the light-emitting element 3. More specifically, the position P is shifted from the focal point F in a direction along an optical axis ax of the condensing lens 302 (i.e., P is axially shifted from F along ax).

Thus, even when the light LL is reflected from the quarter wavelength plate 303, the windows 2012 and 2013 of the atomic cell 201, or the light-receiving element 202, the returned light LL1 (indicated by a two-dot chain line) which is the reflected light returns along a light path that is different from the emitted light LL so that it is concentrated at a position (a condensing point P1) displaced from the focal point F and on an opposite side of the focal point F relative to the position P (note that P1 and P are located on opposite sides of F).

Therefore, the light-emitting element 3 is located in a region which has low light density and is shifted from the condensing point P1 of the returned light LL1 in the direction of (along) the optical axis ax. Thus, as illustrated in FIG. 6, the intensity (an indicted by a two-dot chain line in FIG. 6) of the returned light to the light-emitting element 3 in the atomic oscillator 1 is considerably less than the intensity (b indicated by a solid line in FIG. 6) of the returned light of the above-described atomic oscillator 1X. A “portion of the light-emitting element 3 from which the light LL is emitted” is, for example, an end surface of the resonator from which the light LL is emitted and which is included in the light-emitting element 3. On the horizontal axis of FIG. 6, a center of the portion of the light-emitting element 3 from which the light LL is emitted is a reference (0).

As illustrated in FIG. 5, in the embodiment, the position P of the light-emitting element 3 is located closer to the condensing lens 302 than the focal point F of the condensing lens 302. Therefore, the condensing point P1 is located farther from the condensing lens 302 than the focal point F. Thus, the light LL diverges from the condensing lens 302 as it propagates toward the atomic cell 201 (the light LL is not parallel). If desired, the position P of the light-emitting element 3 may be located on the opposite side of the focal point F of the condensing lens 302 (i.e., farther from the condensing lens 302 than the focal point F). In this case, the condensing point P1 will be located closer to the condensing lens 302 than the position P of the light-emitting element 3. Thus, the light LL will converge from the condensing lens 302 as it propagates toward the atomic cell 201 (the light LL is not parallel). When the position P of the light-emitting element 3 is located nearer the condensing lens 302 than the focal point F of the condensing lens 302, a spot diameter of the returned light LL1 on a plane h passing vertically through the position P relative to the optical axis ax is larger than when the position P of the light-emitting element 3 is located farther from the condensing lens 302 than the focal point F of the condensing lens 302. Accordingly, when the position P of the light-emitting element 3 is located nearer the condensing lens 302 than the focal point F of the condensing lens 302, the amount of returned light LL1 incident on the light-emitting element 3 can be further reduced than when the position P of the light-emitting element 3 is located farther from the condensing lens 302 than the focal point F of the condensing lens 302.

In the embodiment, the position P of the light-emitting element 3 is located on the optical axis ax of the condensing lens 302. Thus, the symmetry of the light LL to the optical axis ax can be raised. Therefore, there is the advantage that it is easy to achieve uniformity of the power density of the light LL in the atomic cell 201, and consequently it is easy to improve the oscillation characteristics (in particular, short-term frequency stability) of the atomic oscillator 1. However, the position P of the light-emitting element 3 may be shifted (be separated) from the optical axis ax of the condensing lens 302. In this case, the center of the returned light LL1 can be shifted from the light-emitting element 3. Therefore, even when a distance between the focal point F and the position P is relatively small, the amount of returned light LL1 incident on the light-emitting element 3 can be reduced.

As described above, the condensing point P1 of the returned light LL1 is located at a position that is selected in accordance with the position P of the light-emitting element 3 and with respect to the focal point F of the condensing lens 302. The parallelism of the light LL emitted from the condensing lens 302 differs in accordance with the position P of the light-emitting element 3 with respect to the focal point F of the condensing lens 302. From this viewpoint, a distance between the focal point F of the condensing lens 302 and the position P of the light-emitting element 3 is preferably equal to or greater than 0.01 times and equal to or less than 0.2 times a focal length of the condensing lens 302 (a distance between the center of the condensing lens 302 and the focal point F), and is more preferably equal to or greater than 0.05 times and equal to or greater than 0.1 times the focal length. Thus, it is possible to appropriately exert the advantage obtained by parallelizing the light LL by the above-described condensing lens 302 and reduce the amount of returned light LL1 incident on the light-emitting element 3.

From the same viewpoint, the light LL emitted through the condensing lens 302 preferably diverges or converges within a range of ±5° (excluding 0°) with respect to the parallelized light inside the atomic cell 201 and more preferably diverges or converges within a range of ±3° (excluding 0°). Thus, it is possible to reduce the intensity of the returned light LL1 incident on the light-emitting element 3 (the amount of incident light) while partly exerting the advantage obtained when the above-described condensing lens 302 causes the light LL to become the parallel light without being hindered.

A positional relation between the focal point F of the condensing lens 302 and the position P of the light-emitting element 3 can be adjusted by changing at least one of the installation position of the light-emitting element 3 and the focal length of the condensing lens 302. Here, the focal length of the condensing lens 302 can be changed by changing a material (refractive index) and curvature of the condensing lens 302.

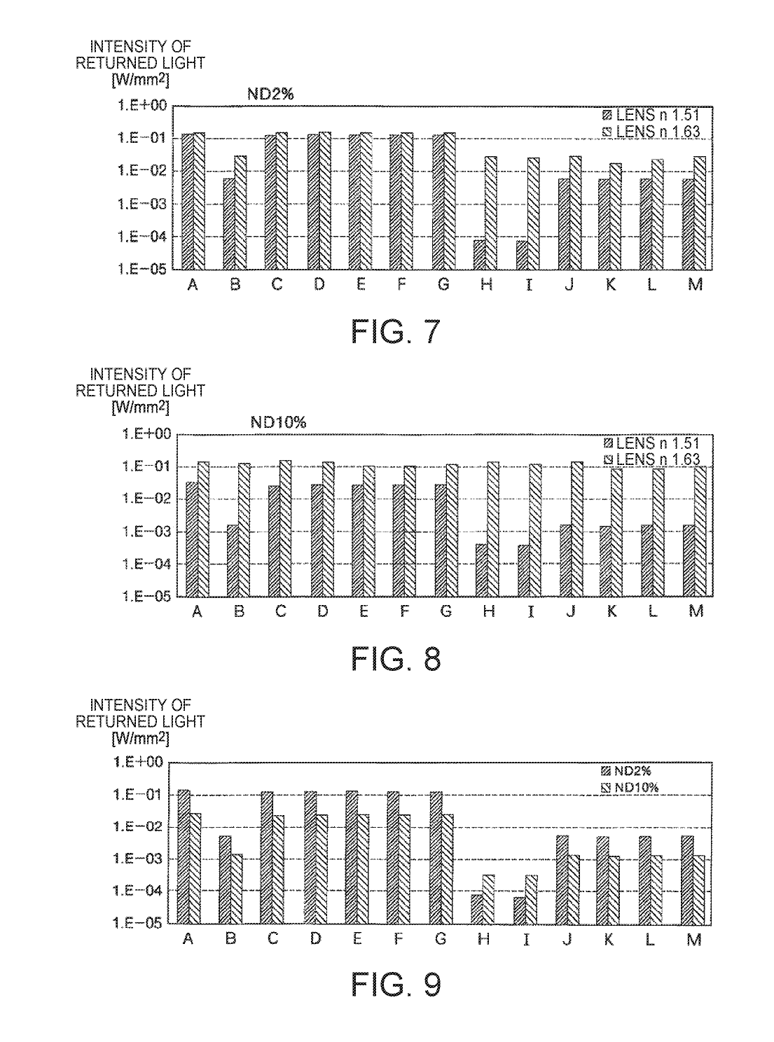

As described above, by not parallelizing the light LL emitted from the condensing lens 302, that is, not matching the position P of the light-emitting element 3 with the focal point F of the condensing lens 302, it is possible to reduce the intensity of the returned light LL1 incident on the light-emitting element 3 (the amount of incident light). To confirm such an advantage, the intensity of the returned light incident on the light-emitting element 3 was measured by simulation. The measurement result is illustrated in FIGS. 7 to 9.

FIG. 7 is a graph illustrating a relation between the intensity of the returned light (returned light when condensing by the condensing lens and reflection from another component are considered) and various conditions (A to M) when transmittance of the light reduction filter is 2%. FIG. 8 is a graph illustrating a relation between the intensity of the returned light (returned light when condensing by the condensing lens and reflection from another component are considered) and the various conditions (A to M) when transmittance of a light reduction filter is 10%. FIG. 9 is a graph illustrating a relation between the intensity of the returned light (returned light when condensing by the condensing lens and reflection from another component are considered) and the various conditions (A to M) when a refractive index of the condensing lens is 1.51.

Here, in FIGS. 7 to 9, condition “A” indicates a case in which an anti-reflection film (AR coat) is not provided in none of the window 56, the light reduction filter 301, the condensing lens 302, the quarter wavelength plate 303, the atomic cell 201, and the light-receiving element 202. Condition “B” indicates a case in which an anti-reflection film is provided on the surface of the window 56 on the side of the light-emitting element 3. Condition “C” indicates a case in which an anti-reflection film is provided on the surface of the light reduction filter 301 on the side of the light-emitting element 3. Condition “D” indicates a case in which an anti-reflection film is provided on the surface of the condensing lens 302 on the side of the light-emitting element 3. Condition “E” indicates a case in which an anti-reflection film is provided on the surface of the quarter wavelength plate 303 on the side of the light-emitting element 3. Condition “F” indicates a case in which an anti-reflection film is provided on the surface of the window 2012 of the atomic cell 201 on the side of the light-emitting element 3. Condition “G” indicates a case in which an anti-reflection film is provided on the light reception surface of light-receiving element 202. Condition “H” indicates a case in which an anti-reflection film is provided on each of the surface of the window 56 on the side of the light-emitting element 3 and both surfaces of the light reduction filter 301. Condition “I” indicates a case in which an anti-reflection film is provided on each of the surface of the window 56 on the side of the light-emitting element 3 and the surface of the light reduction filter 301 on the side of the light-emitting element 3. Condition “J” indicates a case in which an anti-reflection film is provided on each of the surface of the window 56 on the side of the light-emitting element 3 and the surface of the condensing lens 302 on the side of the light-emitting element 3. Condition “K” indicates a case in which an anti-reflection film is provided on each of the surface of the window 56 on the side of the light-emitting element 3 and the surface of the quarter wavelength plate 303 on the side of the light-emitting element 3. Condition “L” indicates a case in which an anti-reflection film is provided on each of the surface of the window 56 on the side of the light-emitting element 3 and the surface of the window 2012 of the atomic cell 201 on the side of the light-emitting element 3. Condition “M” indicates a case in which an anti-reflection film is provided on each of the surface of the window 56 on the side of the light-emitting element 3 and the light reception surface of the light-receiving element 202. Here, reflectance of each anti-reflection film is 0.05%.

As illustrated in FIGS. 7 and 8, when a refractive index of the condensing lens 302 is 1.51 (“lens n 1.51” in the drawings), the intensity of the returned light incident on the light-emitting element 3 is less than when the refractive index of the condensing lens 302 is 1.63 (“lens n 1.63” in the drawings). Here, when the refractive index of the condensing lens 302 is 1.51, the position P of the light-emitting element 3 is located nearer the condensing lens 302 than the focal point F of the condensing lens 302. When the refractive index of the condensing lens 302 is 1.63, the position P of the light-emitting element 3 matches the focal point F of the condensing lens 302.

As illustrated in FIGS. 7 and 8, when conditions “A” to “G” are compared in a case in which the refractive index of the condensing lens 302 is 1.51 (condition “B”), it can be understood that the advantage that the intensity of the returned light incident on the light-emitting element 3 is set to be less when the anti-reflection film is provided in the window 56 is considerable, compared to the other conditions. When conditions “H” to “M” are compared in a case in which the refractive index of the condensing lens 302 is 1.51, it can be understood that the advantage that the intensity of the returned light incident on the light-emitting element 3 is less when the anti-reflection film is provided in the window 56 (conditions “H” and “I”) and the anti-reflection film is further provided in the light reduction filter 301 is considerable, compared to the other conditions.

As illustrated in FIG. 9, when the refractive index of the condensing lens 302 is 1.51, it can be understood that the advantage that the intensity of the returned light incident on the light-emitting element 3 is less is considerable, compared to when the transmittance of the light reduction filter 301 is 10% (“ND 10%” in the drawing) and the transmittance of the light reduction filter 301 is 2% (“ND 2%” in the drawing), under conditions “A” to “G” and conditions “J” to “M”. On the other hand, when the transmittance of the light reduction filter 301 is 2% (“ND 2%” in the drawing), it can be understood that the advantage that the intensity of the returned light incident on the light-emitting element 3 is less is considerable, compared to when the transmittance of the light reduction filter 301 is 10% (“ND 10%” in the drawing), under condition “H” and condition “I”.

Accordingly, when the anti-reflection film is provided in the window 56 and the anti-reflection film is not provided in the light reduction filter 301 (condition “B”), it is preferable to reduce the output intensity of the light-emitting element 3 and increase transmittance of the light reduction filter 301 in order to effectively decrease the intensity of the returned light incident on the light-emitting element 3. In other words, when the output intensity of the light-emitting element 3 is relatively small and the transmittance of the light reduction filter 301 is relatively large, it is preferable to provide the anti-reflection film in the window 56 and provide no anti-reflection film in the light reduction filter 301 (condition “B”). Thus, it is possible to effectively decrease the intensity of the returned light incident on the light-emitting element 3.

On the other hand, when the anti-reflection films are provided in both the window 56 and the light reduction filter 301 (condition “H” and condition “I”), it is preferable to increase the output intensity of the light-emitting element 3 and decrease the transmittance of the light reduction filter 301 in order to effectively decrease the intensity of the returned light incident on the light-emitting element 3. In other words, when the output intensity of the light-emitting element 3 is relatively large and the transmittance of the light reduction filter 301 is relatively small, it is preferable to provide the anti-reflection films in both the window 56 and the light reduction filter 301 (condition “H” and condition “I”). Thus, it is possible to effectively decrease the intensity of the returned light incident on the light-emitting element 3.

Under condition “H” and condition “I”, it can be understood that the advantage that the intensity of the returned light incident on the light-emitting element 3 is less, compared to the other conditions. It is theorized that this is because of the following a and b.

a. Since the window 56 is much closer to the light-emitting element 3 than the other optical elements (the condensing lens 302, the quarter wavelength plate 303, the atomic cell 201, and the light-receiving element 202), an influence of reflected light from the window 56 on the light returned to the light-emitting element 3 is greater than reflected light from the other optical elements.

b. Since the intensity of the light LL transmitted through the light reduction filter 301 considerably attenuates, an influence of the reflected light from the other optical elements on the side of the atomic cell 201 on the light returned to the light-emitting element 3 is less than the light reduction filter.

As described above, the atomic oscillator 1 includes the atomic cell 201 in which an alkali metal is sealed, the light-emitting element 3 that emits the light LL to be radiated to the alkali metal inside the atomic cell 201, the light-receiving element 202 that receives the light LL transmitted through the atomic cell 201 and outputs a signal in accordance with a light reception intensity of the light, and the condensing lens 302 which is a “lens” that disposed between the light-emitting element 3 and the atomic cell 201. The focal point F of the condensing lens 302 does not match the portion of the light-emitting element 3 from which the light LL is emitted in the direction of (along) the optical axis ax (the optical axis direction). Thus, the condensing lens 302 causes the light LL to diverge (or converge) toward the atomic cell 201, that is, emits the light LL in a non-parallel state.

In the atomic oscillator 1, the condensing lens 302 disposed between the light-emitting element 3 and the atomic cell 201 causes the light LL from the light-emitting element 3 to diverge (or converge) and propagate toward the atomic cell 201 (in other words, a focal point is formed at a position shifted from the portion of the light-emitting element 3 from which the light is emitted in the direction along the optical axis ax). Therefore, even when the light LL is reflected from the atomic cell 201, the light-receiving element 202, or the like, the reflected light can be concentrated at a different position than that of the light-emitting element 3 (in particular, the portion from which the light LL is emitted). Therefore, the amount of reflected light incident as the returned light LL1 on the light-emitting element 3 is reduced, and thus it is possible to reduce an output variation (a wavelength variation or an intensity variation) of the light-emitting element 3 caused by the returned light LL1. As a result, it is possible to improve the frequency characteristics (in particular, short-term frequency stability) of the atomic oscillator 1.

As described above, the condensing lens 302 can cause the light LL to diverge toward the atomic cell 201. It is easier to reduce the intensity of the returned light LL1 to the light-emitting element 3 (the amount of incident light) using divergent light as compared to a case in which the condensing lens 302 causes the light to converge toward the atomic cell 201.

### Second Embodiment

An atomic oscillator 100 according to a second embodiment will now be described. The same reference numerals are given to the same constituent members as those of the first embodiment and a duplicate description thereof will be omitted. Differences from those of the foregoing embodiment will be mainly described.

The atomic oscillator 100 according to the second embodiment is different from the atomic oscillator 1 according to the foregoing embodiment with respect to a light path of the light-emitting element.

### Light Path of Light-Emitting Element

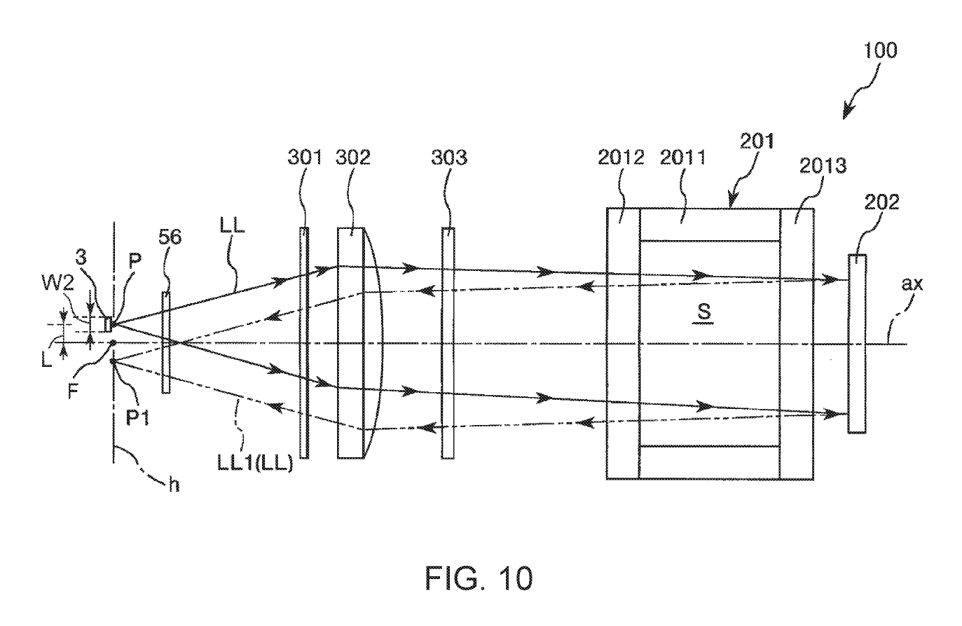

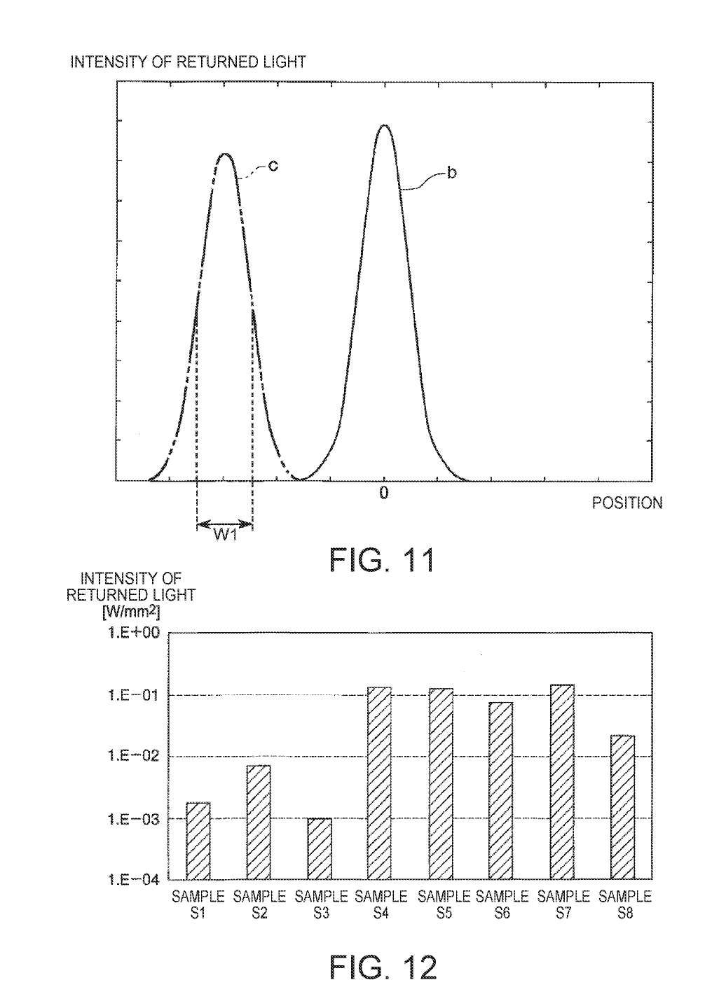

FIG. 10 is a schematic diagram illustrating a light path of the atomic oscillator 100 illustrated in FIG. 2 (when the light-emitting element is disposed at a position laterally shifted from the optical axis ax of the condensing lens). FIG. 11 is a graph illustrating a relation between the intensity of the returned light and a distance (position) from the optical axis illustrated in FIGS. 4 and 10 (returned light when only light concentrated by the condensing lens is considered).

As illustrated in FIG. 10, the atomic oscillator 100 according to the embodiment is configured such that the light LL traveling from the condensing lens 302 to the atomic cell 201 is not parallel to the optical axis ax of the condensing lens 302. That is, the atomic oscillator 100 is configured such that the position P of a light emission portion of the light-emitting element 3 (a portion from which the light LL is emitted) does not match a focal point F which is a focal spot of the condensing lens 302 on the side of the light-emitting element 3. More specifically, the position P is shifted (separated, spaced apart, laterally offset) from the optical axis ax of the condensing lens 302. Thus, even when the light LL is reflected from the quarter wavelength plate 303, the windows 2012 and 2013 of the atomic cell 201, or the light-receiving element 202, the returned light LL1 which is the reflected light is concentrated at a position (a condensing point P1) that is opposite to the position P with respect to the focal point F (i.e., the light is concentrated at P1; and P1 and P are located on opposite sides of F). Therefore, as illustrated in FIG. 10, the light-emitting element 3 is located within a region (a region in which a light density of the reflected light is considerably low) shifted (laterally displaced) from the condensing point P1 of the returned light LL1 in a direction lateral (or radial if the optical axis ax is considered axial) to the optical axis ax. The intensity (c indicated by a two-dot chain line in FIG. 11) of the returned light to the light-emitting element 3 in the atomic oscillator 100 can be considerably further reduced than the intensity (b indicated by a solid line in FIG. 11) of the returned light of the above-described atomic oscillator 1X.

A “portion of the light-emitting element 3 from which the light LL is emitted” is an end surface of the resonator from which the light LL is emitted and which is included in the light-emitting element 3. On the horizontal axis of FIG. 11, a center of the portion of the light-emitting element 3 from which the light LL is emitted is a reference (0).

Here, the condensing point P1 is located on a side of the optical axis ax that is opposite to the position P of the light-emitting element 3 with respect to the optical axis ax (i.e., P1 and P are located on opposite sides of ax). The position P of the light-emitting element 3 is located on a plane h which is a plane having the optical axis ax as a normal and passing through the focal point F. Thus, since the condensing point P1 is located on the plane h, a spot diameter of the returned light LL1 on the plane h can be considerably small. Therefore, since the position P can be shifted slightly from the focal point F on the plane h, it is possible to considerably reduce the incidence of the returned light LL1 on the light-emitting element 3.

Even when the position P of the light-emitting element 3 is shifted from the plane h in the direction of the optical axis ax (i.e., along the optical axis ax), it is possible to reduce the incidence of the returned light LL1 on the light-emitting element 3. However, in order to cause the spot diameter of the returned light LL1 on the plane h to be considerably small, a distance between the position P and the plane h (a distance in the direction of (along) the optical axis ax) is preferably equal to or less than a focal length of the condensing lens 302 (equal to or less than the length of a beam waist of the returned light LL1). An emission direction of the light LL from the light-emitting element 3 (a direction oriented along the central axis of the light LL) may be tilted relative to the optical axis ax of the condensing lens 302 in accordance with a distance L between the position P and the focal point F or may be parallel to the optical axis ax of the condensing lens 302 irrespective of the distance between the position P and the focal point F.

When a shift amount of the position P from the focal point F is small, the light LL emitted from the condensing lens 302 can be set to a state close to parallel light, and thus it is possible to considerably exert the advantage by the parallel light described above. From the viewpoint in which the advantage is compatible with the advantage of reducing the incidence of the returned light LL1 on the light-emitting element 3, the distance L between the position P of the light-emitting element 3 and the optical axis ax of the condensing lens 302 is preferably equal to or greater than a width W1 (see FIG. 11) of the returned light LL1 and equal to or less than a width W2 of the light-emitting element 3, and is more preferably equal to or greater than a width W of the portion of the light-emitting element 3 from which the light LL is emitted and equal to or less than the width W2 of the light-emitting element 3. The width W1 of the returned light LL1 is a full width at half maximum (FWHM) of the returned light LL1.

From the same viewpoint, the light LL emitted from the condensing lens 302 is preferably tilted relative to the optical axis ax within a range of ±5° inside the atomic cell 201 and is more preferably tilted relative to the optical axis ax within a range of ±3°. Thus, it is possible to reduce the amount of the returned light LL1 incident on the light-emitting element 3 while appropriately exerting the advantage obtained when the above-described condensing lens 302 causes the light LL to become the parallel light.

As described above, by causing the light LL emitted from the condensing lens 302 to be non-parallel relative to the optical axis ax, that is, by shifting the position P of the light-emitting element 3 from the optical axis ax of the condensing lens 302, it is possible to reduce the amount of returned light LL1 incident on the light-emitting element 3. To confirm such an advantage, the intensity of the returned light incident on the light-emitting element 3 was measured by simulation. The measurement result is illustrated in FIG. 12.

FIG. 12 is a graph illustrating a relation between the intensity of the returned light (returned light when condensing by the condensing lens and reflection from another component are considered) and various conditions (Samples S1 to S8).

Here, in FIG. 12, “Sample S1” indicates a case in which the light-emitting element 3 is shifted from the optical axis ax of the condensing lens 302 (the distance L=0.3 mm) and an anti-reflection film (an AR coat with reflectance of 0.05%) is provided on each of both surfaces of the window 56 and the surface of the light reduction filter 301 on the side of the light-emitting element 3. “Sample S2” indicates a case in which Sample S2 is configured similarly to Sample 1 is provided except that no anti-reflection film is provided in the light reduction filter 301. “Sample S3” indicates a case in which Sample S3 is configured similarly to Sample S1 except that the window 56 has the same light reduction function as the light reduction filter 301 instead of the light reduction filter 301 and thus the window 56 also serves as the light reduction filter 301. “Sample S4” indicates a case in which Sample S4 is configured similarly to Sample S1 is provided except that no anti-reflection film is provided in the window 56 and the light reduction filter 301. “Sample S5” indicates a case in which Sample S5 is configured similarly to Sample S1 is provided except that no anti-reflection film is provided in the window 56. “Sample S6” indicates a case in which Sample S6 is configured similarly to Sample S3 is provided except that no anti-reflection film is provided in the window 56. “Sample S7” indicates a case in which Sample S7 is configured similarly to Sample S1 is provided except that the light-emitting element 3 is disposed on the optical axis ax (on the focal point F) of the condensing lens and no anti-reflection film is provided in the window 56 and the light reduction filter 301. “Sample S8” indicates a case in which Sample S8 is configured similarly to Sample S1 is provided except that the light-emitting element 3 is disposed on the optical axis ax of the condensing lens (the focal point F).

As illustrated in FIG. 12, when Samples S1 and S8 in which only whether the light-emitting element 3 is shifted from the optical axis ax of the condensing lens 302 is different are compared, the intensity of the returned light incident on the light-emitting element 3 is less in Sample S1 than in Sample S8. Similarly, when Samples S4 and S7 in which only whether the light-emitting element 3 is shifted from the optical axis ax of the condensing lens 302 is different are compared, the intensity of the returned light incident on the light-emitting element 3 is less in Sample S4 than in Sample S7. Here, a difference in the intensity of the returned light incident on the light-emitting element 3 between Samples S4 and S7 is less than a difference in the intensity of the returned light incident on the light-emitting element 3 between Samples S1 and S8. This means that the advantage of reducing the returned light to the light-emitting element 3 by providing the anti-reflection films in the window 56 and the light reduction filter 301 is greater than the advantage of reducing the returned light to the light-emitting element 3 by shifting the light-emitting element 3 from the optical axis ax of the condensing lens 302.

Compared to Samples S2, S4, and S5, it can be understood that the advantage of reducing the returned light to the light-emitting element 3 is greater by providing the anti-reflection film in the window 56 than by providing the anti-reflection film in the light reduction filter 301. When the window 56 also serves as the light reduction filter 301 as in Sample S3, the advantage of reducing the returned light to the light-emitting element 3 is the greatest. It can also be confirmed that the advantage obtained by providing the anti-reflection films in the window 56 is the same as the advantage obtained by providing the anti-reflection film on only the surface of the window 56 on the side of the light-emitting element 3.

In this way, by providing the anti-reflection film in at least the window 56 between the window 56 and the light reduction filter 301, the advantage of reducing the returned light to the light-emitting element 3 is great. It is theorized that this is because of the following a and b.

a. Since the window 56 is much closer to the light-emitting element 3 than the other optical elements (the condensing lens 302, the quarter wavelength plate 303, the atomic cell 201, and the light-receiving element 202), an influence of reflected light from the window 56 on the returned light to the light-emitting element 3 is greater than reflected light from the other optical elements.

b. Since the intensity of the light LL transmitted through the light reduction filter 301 considerably attenuates, an influence of the reflected light from the other optical elements on the side of the atomic cell 201 on the returned light to the light-emitting element 3 is less than the light reduction filter.

As described above, the atomic oscillator 100 includes the atomic cell 201 in which an alkali metal is sealed, the light-emitting element 3 that emits the light LL to be radiated to the alkali metal inside the atomic cell 201, the light-receiving element 202 that receives the light LL transmitted through the atomic cell 201 and outputs a signal in accordance with a light reception intensity of the light, and the condensing lens 302 which is a “lens” that disposed between the light-emitting element 3 and the atomic cell 201. In particular, the portion of the light-emitting element 3 from which the light LL is emitted is separated from the optical axis ax of the condensing lens 302. Alternatively, the condensing lens 302 is configured to also emit the light LL toward the atomic cell 201 in a direction that is tilted relative to the optical axis ax of the condensing lens 302.

In the atomic oscillator 100, the condensing lens 302 disposed between the light-emitting element 3 and the atomic cell 201 emits the light LL from the light-emitting element 3 toward the atomic cell 201 in the direction that is tilted relative to the optical axis ax of the condensing lens 302 (in other words, the portion of the light-emitting element 3 from which the light LL is emitted is separated from the optical axis ax of the condensing lens 302). Therefore, even when the light LL is reflected from the atomic cell 201, the light-receiving element 202, or the like, the reflected light can be concentrated at a different position than that of the light-emitting element 3 (in particular, the portion from which the light LL is emitted). Therefore, the amount of reflected light incident as the returned light LL1 on the light-emitting element 3 is reduced, and thus it is possible to reduce an output variation (a wavelength variation or an intensity variation) of the light-emitting element 3 caused by the returned light LL1. As a result, it is possible to improve the frequency characteristics (in particular, short-term frequency stability) of the atomic oscillator 100.

In the second embodiment, a distance between the position P which is the portion of the light-emitting element 3 from which the light LL is emitted and the plane h which passes through the focal point F of the condensing lens 302 and has the optical axis as a normal is equal to or less than a focal length of the condensing lens 302. In the illustrated example, the distance is zero because the position P resides along the plane h. Thus, it is possible to effectively reduce the amount of returned light LL1 to the light-emitting element 3 while causing the distance between the light-emitting element 3 and the condensing lens 302 to be relatively small.

The atomic oscillators 1 and 100 according to the above-described first and second embodiments include the light reduction filter 301 disposed between the light-emitting element 3 and the condensing lens 302. Thus, it is possible to easily optimize the intensity of the light LL radiated to the alkali metal inside the atomic cell 201. Since the returned light LL1 also passes through the light reduction filter 301, it is possible to further reduce the intensity of the returned light LL1 to the light-emitting element 3 (the amount of incident light).

Here, the light reduction filter 301 is preferably a filter containing a substance that absorbs light, that is, the light reduction filter 301 is preferably a so-called absorption type light reduction filter. Thus, it is possible to reduce the amount of returned light that is formed when the light LL from the light-emitting element 3 is reflected from the light reduction filter 301.

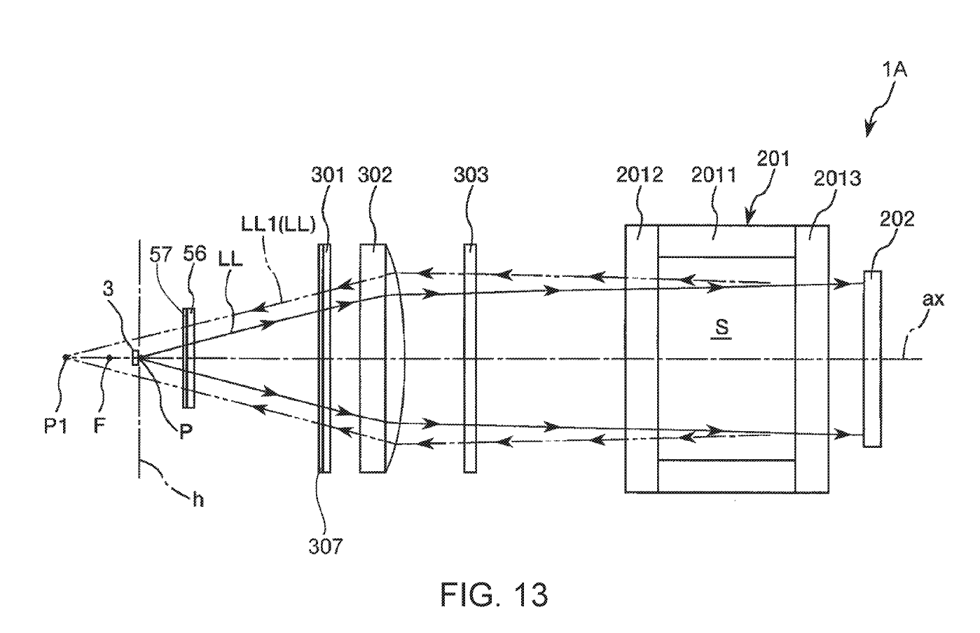

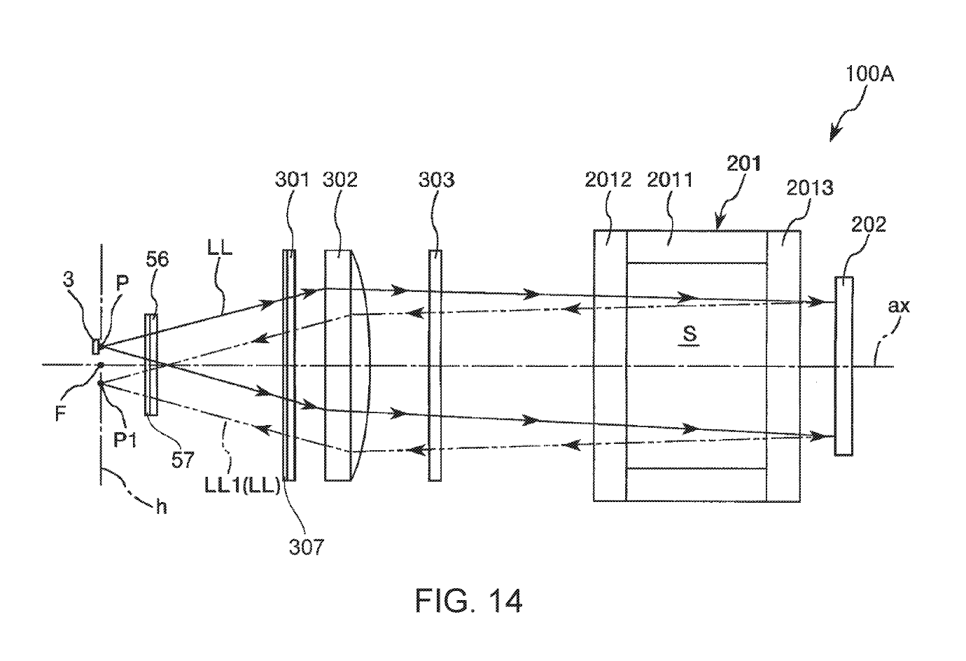

A reflection reduction layer 307 which is an anti-reflection film (an optical thin film or the like) is preferably formed on the light reduction filter 301 as in an atomic oscillator 1A illustrated in FIG. 13 and an atomic oscillator 100A illustrated in FIG. 14. That is, the atomic oscillators 1 and 100 preferably include the reflection reduction layer 307 that is disposed on the light reduction filter 301 (the surface on the side of (facing) the light-emitting element 3 in the drawings) and reduces the reflection of the light LL. Thus, it is possible to reduce the amount of returned light that is formed when the light LL from the light-emitting element 3 is reflected from the light reduction filter 301.

The atomic oscillators 1 and 100 include the package 5 that accommodates the light-emitting element 3. The package 5 includes the window 56 through which the light LL is transmitted. Thus, it is possible to adjust the temperature of the light-emitting element 3 independently from the atomic cell 201. As a result, it is possible to easily reduce an output variation due to a temperature variation of the light-emitting element 3.

FIG. 13 is a schematic diagram illustrating a modification example of the atomic oscillator illustrated in FIG. 5. FIG. 14 is a schematic diagram illustrating a modification example of the atomic oscillator illustrated in FIG. 10. As described in the foregoing embodiments, as in the atomic oscillator 1A illustrated in FIG. 13 and the atomic oscillator 100A illustrated in FIG. 14, the reflection reduction layer 57 which is an anti-reflection film (an optical thin film or the like) is preferably formed on the surface of the window 56 on the side of the light-emitting element 3 which is closest to the light-emitting element 3 among the plurality of optical elements between the light-emitting element 3 and the light-receiving element 202. That is, the atomic oscillators 1 and 100 preferably include the reflection reduction layer 57 that is disposed on the surface of the window 56 on the side of the light-emitting element 3 and that reduces reflection of the light LL. Thus, it is possible to reduce the amount of returned light that is formed when the light LL from the light-emitting element 3 is reflected from the window 56. Here, since the window 56 of the package 5 accommodating the light-emitting element 3 is located at a position very close to the light-emitting element 3, the light LL from the light-emitting element 3 is easily incident as returned light on the light-emitting element 3 when the light LL is reflected from the window 56. Therefore, when the reflected light from the window 56 is reduced, it is particularly effective to reduce the amount of returned light to the light-emitting element 3.

The window 56 may have the same light reduction function as the light reduction filter 301. That is, the window 56 may be a light reduction filter. In this case, it is possible to reduce the amount of returned light that is formed when the light LL from the light-emitting element 3 is reflected from the light reduction filter. Since the light reduction filter 301 formed outside of the package 5 can be omitted, it is possible to simplify the configuration of the atomic oscillators 1 and 100 and reduce the cost.

### 2. Electronic Apparatus

The atomic oscillator 1 or 1000 described above can be employed in any of various electronic apparatuses. Hereinafter, one embodiment of an electronic apparatus will be described.

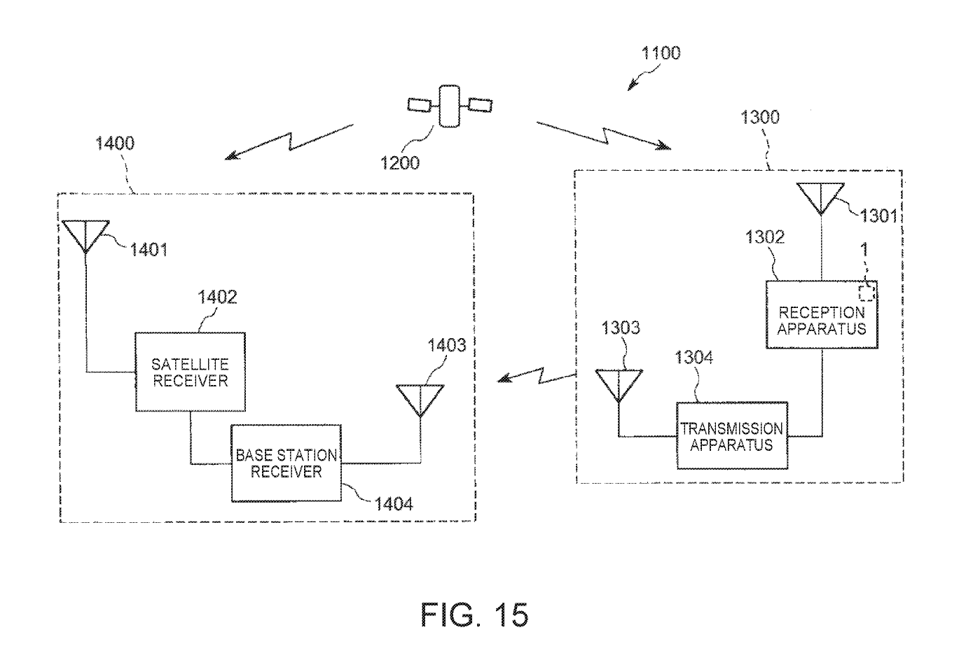

FIG. 15 is a diagram illustrating an overall configuration when the atomic oscillator according to the embodiment is used in a positioning system in which a Global Positioning System (GPS) satellite is used.

A positioning system 1100 illustrated in FIG. 15 is configured to include a GPS satellite 1200, a base station apparatus 1300, and a GPS reception apparatus 1400.

The GPS satellite 1200 transmits positioning information (a GPS signal).

The base station apparatus 1300 includes a reception apparatus 1302 that receives the positioning information with high precision from the GPS satellite 1200 via an antenna 1301 installed at, for example, an electronic standard point (GPS continuous observation station) and a transmission apparatus 1304 that transmits the positional information received by the reception apparatus 1302 via an antenna 1303.

Here, the reception apparatus 1302 is an electronic apparatus that includes the atomic oscillator 1 (the light-emitting element module 10) of the above-described embodiment as a standard frequency oscillation source. The positional information received by the reception apparatus 1302 is transmitted in real time by the transmission apparatus 1304.

The GPS reception apparatus 1400 includes a satellite receiver 1402 that receives the positioning information from the GPS satellite 1200 via an antenna 1401 and a base station receiver 1404 that receives the positional information from the base station apparatus 1300 via an antenna 1403.

The reception apparatus 1302 which is an “electronic apparatus” included in the above-described positioning system 1100 includes the atomic oscillator 1. Thus, it is possible to have the advantages (for example, excellent frequency characteristics) of the atomic oscillator 1 and exert excellent characteristics.

The electronic apparatus including the light-emitting element module is not limited to the above-described electronic apparatus. The invention can be applied to, for example, a smartphone, a tablet terminal, a timepiece, a mobile phone, a digital still camera, an ink jet ejection apparatus (for example, an ink jet printer), a personal computer (a mobile personal computer or a laptop personal computer), a television, a video camera, a video tape recorder, a car navigation apparatus, a pager, an electronic organizer (also including a communication system), an electronic dictionary, a calculator, an electronic game apparatus, a word processor, a workstation, a television telephone, a security television monitor, electronic binoculars, a POS terminal, a medical apparatus (for example, an electronic thermometer, a blood-pressure meter, a blood-sugar meter, an electrocardiographic apparatus, an ultrasonic diagnostic apparatus, or an electronic endoscopy), a fish finder, various measurement apparatuses, meters (for example, meters for cars, airplanes, and ships), a flight simulator, a digital terrestrial broadcast, and a mobile phone base station.

### 3. Vehicle

The above-described atomic oscillator 1 or 100 can be included in any of various vehicles. Hereinafter, an embodiment of the vehicle will be described.

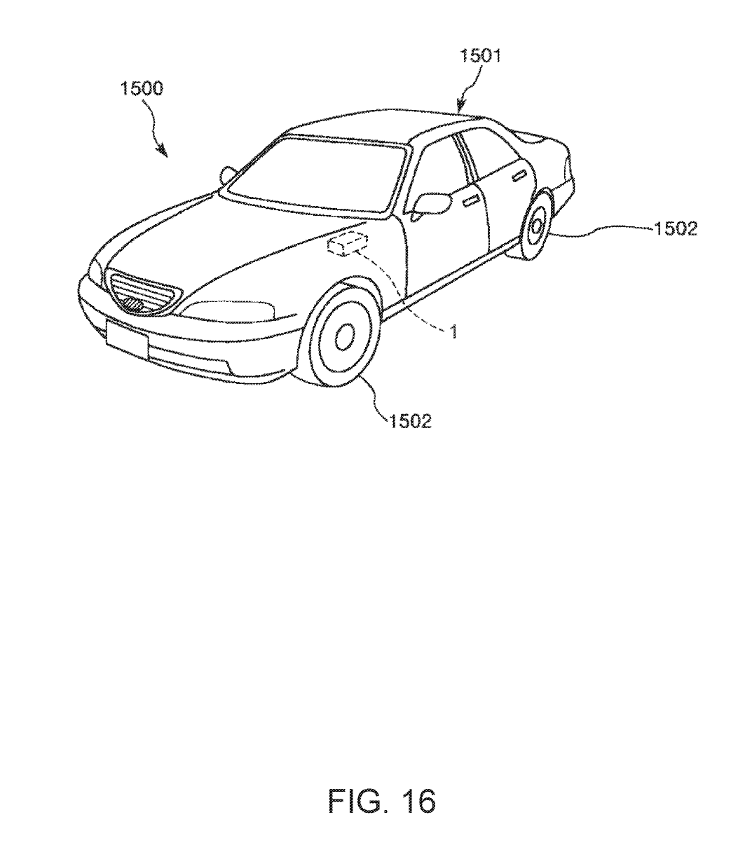

FIG. 16 is a diagram illustrating an embodiment of the vehicle.

In FIG. 16, a vehicle 1500 includes a body 1501 and four wheels 1502 and is configured to rotate the wheels 1502 by a power source (engine) (not illustrated) installed in the body 1501. The vehicle 1500 contains the atomic oscillator 1.

The above-described vehicle 1500 includes the atomic oscillator 1. Thus, it is possible to have the advantages (for example, excellent frequency characteristics) of the atomic oscillator 1 and exert excellent characteristics.

The atomic oscillator, the electronic apparatus, and the vehicle according to the invention have been described above according to the illustrated embodiments, but the invention is not limited thereto.

The configuration of each part of the invention can be replaced with any configuration that has the same function as that according to the above-described embodiment and any configuration can also be added.

In the above-described embodiment, the atomic oscillator that resonantly transitions cesium or the like using coherent population trapping by two kinds of light with different wavelengths has been described as an example, but the invention is not limited thereto. The invention can also be applied to an atomic oscillator that resonantly transitions rubidium or the like using a double resonance phenomenon by light and microwaves.

In the above-described embodiment, the case in which two packages, the package accommodating the light-emitting element and the package accommodating the atomic cell and the light-receiving element are included has been described as an example. However, the light-emitting element, the atomic cell, and the light-receiving element may be accommodated in a package having one common inner space.

The entire disclosures of Japanese Patent Application Nos. 2017-014833 and 2017-014834 both filed Jan. 30, 2017 are expressly incorporated by reference herein.

What is claimed is:

1. An atomic oscillator comprising:
an atomic cell in which an alkali metal is sealed;
a light-emitting element configured to emit light toward the atomic cell for irradiating the alkali metal, the light-emitting element having a portion from which the light is emitted;
a light-receiving element configured to receive the light transmitted through the atomic cell and to output a signal corresponding to a light reception intensity of the light; and
a lens disposed between the light-emitting element and the atomic cell, the lens having a focal point,
wherein the portion of the light-emitting element from which the light is emitted is spaced apart from the focal point of the lens.

2. The atomic oscillator according to claim 1,
wherein the focal point is axially shifted from the portion from which the light is emitted along an optical axis of the lens.

3. The atomic oscillator according to claim 1,
wherein the lens is configured to cause the light to diverge or converge toward the atomic cell.

4. The atomic oscillator according to claim 1,
wherein the lens is configured to cause the light to diverge toward the atomic cell.

5. The atomic oscillator according to claim 1,
wherein the portion from which the light is emitted is laterally shifted from the focal point relative to an optical axis of the lens.

6. The atomic oscillator according to claim 1,
wherein the light from the lens propagates along a light path that is tilted with respect to an optical axis of the lens.

7. The atomic oscillator according to claim 1,
wherein a distance between the portion from which the light is emitted and a plane passing through the focal point of the lens and having an optical axis of the lens as a normal is equal to or less than a focal length of the lens.

8. The atomic oscillator according to claim 1, further comprising:
a light reduction filter disposed between the light-emitting element and the lens.

9. The atomic oscillator according to claim 8,
wherein the light reduction filter contains a substance configured to absorb the light.

10. The atomic oscillator according to claim 8, further comprising:
a reflection reduction layer disposed on the light reduction filter.

11. The atomic oscillator according to claim 1, further comprising:
a package accommodating the light-emitting element,
wherein the package includes a window through which the light is transmitted.

12. The atomic oscillator according to claim 11, further comprising:
a reflection reduction layer disposed on a surface of the window facing the light-emitting element.

13. The atomic oscillator according to claim 11,
wherein the window is a light reduction filter.

14. An atomic oscillator comprising:
an atomic cell housing an alkali metal;
a vertical resonator surface-emitting laser configured to emit light toward the atomic cell for irradiating the alkali metal, the vertical resonator surface-emitting laser having a resonator end surface from which the light is emitted;
a photodiode configured to receive the light transmitted through the atomic cell and to output a signal corresponding to a received intensity of the light; and
a lens disposed between the light-emitting element and the atomic cell, the lens having a focal point,
wherein the resonator end surface of the light-emitting element is at least one of axially and laterally spaced apart from the focal point of the lens.

15. The atomic oscillator according to claim 14,
wherein the lens is one of a convergent lens and a divergent lens.

16. The atomic oscillator according to claim 14,
wherein the light from the lens propagates along a light path that is tilted with respect to an optical axis of the lens.

17. The atomic oscillator according to claim 14, further comprising:
a light reduction filter disposed between the vertical resonator surface-emitting laser and the lens.

18. The atomic oscillator according to claim 17, further comprising:
a reflection reduction layer disposed on the light reduction filter.

19. The atomic oscillator according to claim 14, further comprising:
a package accommodating the vertical resonator surface-emitting laser, the package including a window through which the light is transmitted, and
a reflection reduction layer disposed on a surface of the window facing the vertical resonator surface-emitting laser.

20. The atomic oscillator according to claim 19,
wherein the window is a light reduction filter.
